(19) United States
(12) Patent Application Publication
(10) Pub. No.: US 2025/0293223 A1
(43) Pub. Date: Sep. 18, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventor: Meng-Jie LEE, Taichung City (TW)

(21) Appl. No.: 18/816,828

(22) Filed: Aug. 27, 2024

(30) Foreign Application Priority Data
Mar. 12, 2024 (TW) 113109039

(51) Int. Cl. H01L 25/16; H01L 23/00; H01L 23/495; H01L 23/498

(52) U.S. Cl. CPC H01L 25/167; H01L 23/49568; H01L 24/16; H01L 23/49827; H01L 24/32; H01L 2224/10126; H01L 2224/16235; H01L 2224/32245; H01L 2924/1903

(57) ABSTRACT

An electronic package and a manufacturing method thereof are provided. The electronic package includes a photonic component, an electronic component and an optical component. The photonic component has a first surface and a second surface opposite thereto, and the first surface is defined with an electrical bonding region and an optical coupling region that are non-overlapping with each other. The electronic component is disposed on the electrical bonding region and is electrically connected to the photonic component. The optical component is disposed on the optical coupling region and is optically connected to the photonic component. The above-mentioned electronic package and manufacturing method thereof employ a 2.5-dimensional stack structure for coupling the optical component without forming a cantilever structure. Therefore, the present disclosure achieves the advantages of high heat dissipation efficiency, simplified manufacturing process, higher yield and shorter process cycle.

### CROSS-REFERENCE TO RELATED APPLICATIONS

The present application is based upon and claims the right of priority to TW patent Application No. 113109039, filed Mar. 12, 2024, the disclosure of which is hereby incorporated by reference herein in its entirety for all purposes.

### BACKGROUND

### 1. Technical Field

The present disclosure relates to a semiconductor packaging process, and more particularly, to an electronic package and a manufacturing method thereof.

### 2. Description of Related Art

In order to cope with the huge data transmission demand of modern network electronic products, co-packaged optics (CPO) using silicon photonics technology has become an inevitable trend. Conventional co-packaged optics include an optical engine composed of a photonic chip and an electronic chip, in which the photonic chip is stacked on top of the electronic chip to form a cantilever structure for coupling optical fibers. However, the cantilever structure is prone to difficult alignment in fibers, resulting in optical signal loss and reduced chip module gross die utilization. In addition, since the electronic chip is embedded in the encapsulants and is unable to reach the heat dissipation member, the heat dissipation effect is thus poor, thereby causing a reduction in the overall performance of the optical engine.

### SUMMARY

In order to solve the above problems, the present disclosure provides an electronic package including a photonic component, an electronic component and an optical component. The photonic component has a first surface and a second surface opposite to the first surface, and the first surface is defined with an electrical bonding region and an optical coupling region that are non-overlapping with each other. The electronic component is disposed on the electrical bonding region and is electrically connected to the photonic component. The optical component is disposed on the optical coupling region and is optically connected to the photonic component.

The present disclosure further provides a method for manufacturing an electronic package including: providing a photonic component, wherein the photonic component has a first surface and a second surface opposite to the first surface, and the first surface is defined with an electrical bonding region and an optical coupling region that are non-overlapping with each other; disposing an electronic component on the electrical bonding region so as to electrically connect the electronic component to the photonic component; and disposing an optical component on the optical coupling region so as to optically connect the optical component to the photonic component.

The electronic package and its manufacturing method of the present disclosure employ a 2.5-dimensional stack structure for coupling optical components without forming a cantilever structure. Therefore, the present disclosure has the advantages of high efficiency of heat dissipation, simplified manufacturing process, higher yield, and shorter process cycle.

### BRIEF DESCRIPTION OF THE DRAWINGS

FIG. 1 to FIG. 3 are schematic cross-sectional views illustrating the method for manufacturing the electronic package according to the present disclosure.

FIG. 4 is a partial top view illustrating the method for manufacturing the electronic package according to the present disclosure.

FIG. 5 and FIG. 6 are schematic cross-sectional views illustrating the method for manufacturing the electronic package according to the present disclosure.

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “lower,” “first,” “second” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

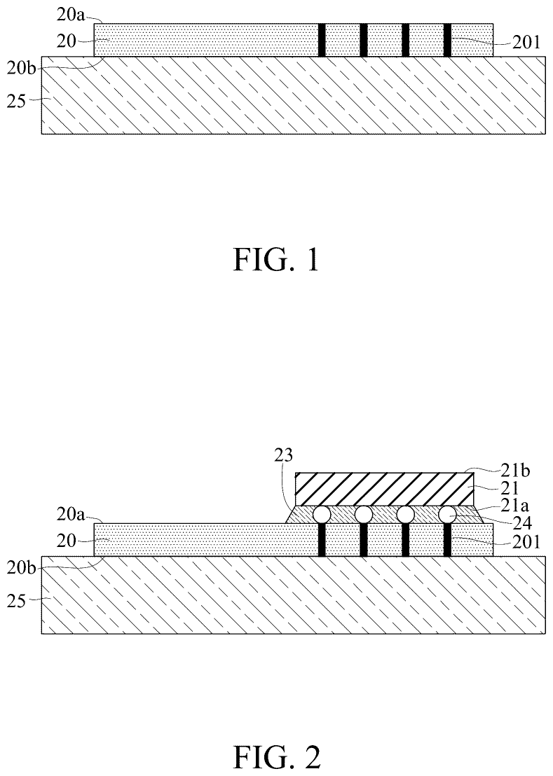

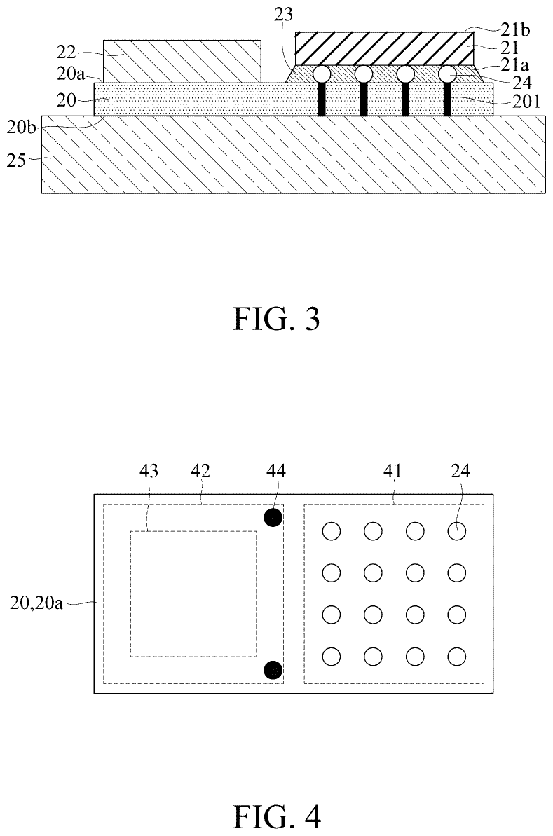

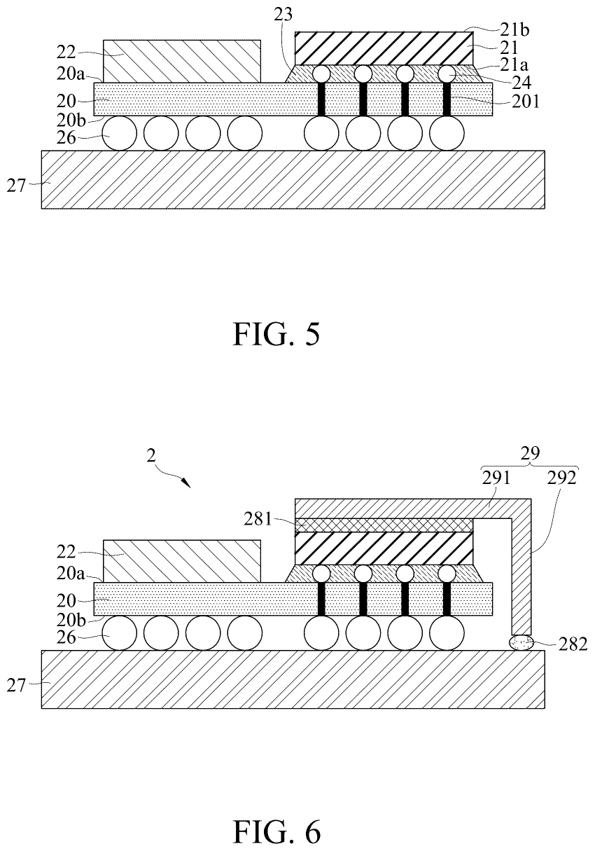

FIG. 1 to FIG. 6 are schematic views illustrating the method for manufacturing an electronic package 2 according to the present disclosure, in which FIG. 1 to FIG. 3, FIG. 5 and FIG. 6 are schematic cross-sectional views of the electronic package 2, and FIG. 4 is a partial top view of the electronic package 2.

First, as shown in FIG. 1, a photonic component 20 is placed on a carrier 25. The photonic component 20 may be, for example, a photonic chip and has a first surface 20a and a second surface 20b opposite to the first surface 20a. For example, the first surface 20a is an upper surface of the photonic component 20, and the second surface 20b is a lower surface of the photonic component 20. A plurality of conductive circuits 201 are formed in the photonic component 20. The conductive circuits 201 are circuits formed by conductive materials for example, through-silicon vias (TSVs) or other forms. The carrier 25 is a carrying plate or other object that can be used to carry the photonic component 20.

As shown in FIG. 2, an electronic component 21 is disposed on the photonic component 20, so that the electronic component 21 is electrically connected to the photonic component 20. The electronic component 21 has an active surface 21a and an inactive surface 21b opposite to the active surface 21a. The electronic component 21 is disposed on the photonic component 20 in a flip-chip manner via the active surface 21a, a plurality of conductive components 24 and an underfill 23, so that the electronic component 21 is electrically connected to the conductive circuits 201 of the photonic component 20 via the plurality of conductive components 24.

The electronic component 21 can be, for example, an active element, a passive element or a combination thereof. The active element 21 is, for example, a semiconductor chip, and the passive element is, for example, a resistor, a capacitor, and/or an inductor. The plurality of conductive components 24 are, for example, conductive pillars or conductive bumps.

As shown in FIG. 3, an optical component 22 is disposed on the photonic component 20, so that the optical component 22 is optically connected to the photonic component 20. For example, the optical component 22 is an optical fiber connector.

As shown in FIG. 4, the first surface 20a of the photonic component 20 is provided with an electrical bonding region 41 and an optical coupling region 42 that are non-overlapping. The plurality of conductive components 24 are disposed in the electrical bonding area 41 for electrically connecting the electronic component 21, so that the electronic component 21 is disposed on the electrical bonding region 41 in the aforementioned flip-chip manner, and is electrically connected to the photonic component 20.

The optical coupling region 42 is configured for coupling the optical component 22. Specifically, the optical coupling region 42 includes an optical coupling surface 43. A grating or an optical guide element (not shown) is provided in the optical coupling surface 43, and the photonic component 20 is optically connected to the optical component 22 via the grating or the optical guide element.

In addition, the optical coupling region 42 further includes at least one limiting structure 44 located outside the optical coupling surface 43. The limiting structure 44 is configured for limiting the position of the optical component 22 when the optical component 22 is optically connected to the aforementioned grating or optical guide element, and thus allowing the optical component 22 and the optical coupling surface 43 to arrive at good coupling efficiency.

In one embodiment of the present disclosure, the photonic chip 20 is in a wafer form, and the electronic package is part of a large-layout package. In other words, the large-layout package is composed of a plurality of electronic packages. Therefore, a singulation process is required for the large-layout package to separate each electronic package.

Next, as shown in FIG. 5, the carrier 25 is removed, and the photonic component 20, the electronic component 21 and the optical component 22 are placed on a carrying structure 27. In particular, the second surface 20b of the photonic component 20 is disposed on the carrying structure 27 and is electrically connected to the carrying structure 27 by a plurality of conductors 26, so that the carrying structure 27 is electrically connected to the electronic component 21 via the conductors 26, the conductive circuits 201 in the photonic component 20, and the conductive components 24.

The plurality of conductors 26 are, for example, conductive pillars or conductive bumps.

The carrying structure 27 is, for example, a package substrate having a core layer and a circuit structure, a package substrate having a coreless circuit structure, a through-silicon interposer (TSI) having TSV and other conductive circuits, or other types of plates.

Next, as shown in FIG. 6, a heat dissipation member 29 is bonded to the electronic component 21 and is coupled to the carrying structure 27. Specifically, the heat dissipation member 29 is a metal configuration and includes a sheet body 291 and a support part 292. The heat dissipation member 29 is bonded to the electronic component 21 via the sheet body 291 and a bonding layer 281, and is coupled to the carrying structure 27 via the support part 292 and an adhesive layer 282.

In one embodiment, the bonding layer 281 can be a thermal interface material (TIM), thermal conductive glue or other suitable materials, and the adhesive layer 282 can be insulating glue, conductive glue or other suitable materials.

As shown in FIG. 4 to FIG. 6, the electronic package 2 obtained by the aforementioned manufacturing method includes a photonic component 20, an electronic component 21, an optical component 22, a carrying structure 27, and a heat dissipation member 29.

The electronic component 21 is disposed on the electrical bonding region 41 on the first surface 20a of the photonic component 20, and is electrically connected to the photonic component 20. Specifically, the active surface 21a of the electronic component 21 is disposed on the electrical bonding region 41 of the photonic component 20 in a flip-chip manner and is electrically connected to the photonic component 20 via the underfill 23 and the plurality of conductive components 24.

The optical component 22 is disposed on the optical coupling region 42 of the first surface 20a of the photonic component 20, and is optically connected to the photonic component 20.

The second surface 20b of the photonic component 20 is disposed on the carrying structure 27 via a plurality of conductors 26, so that the carrying structure 27 is electrically connected to the photonic component 20 via the second surface 20b, thereby the carrying structure 27 is electrically connected to the electronic component 21 via the photonic component 20.

The heat dissipation member 29 is bonded to the electronic component 21 and is configured on the carrying structure 27. Specifically, the sheet body 291 of the heat dissipation member 29 is bonded to the electronic component 21 via the bonding layer 281, and the support part 292 of the heat dissipation member 29 is configured on the carrying structure 27 via the adhesive layer 282.

In the electronic package and method for manufacturing the same of the present disclosure, the electronic component is stacked on top of the photonic component, and the bonding layer and the heat dissipation member are disposed on the electronic component, so as to greatly improve the heat dissipation efficiency of the electronic component.

In addition, a cantilever structure for coupling optical components is not required in the electronic package and method for manufacturing the same of the present disclosure. Therefore, the utilization rate of chip module gross die can be improved, and the difficulty of optical coupling between the photonic component and the optical component can be reduced.

Furthermore, the electronic package and method for manufacturing the same provided in the present disclosure employ a 2.5-dimensional (2.5D) stack structure, that is, a stack structure in which an electronic component and an optical component are disposed on a photonic component. Therefore, compared with the fan-out structure, the electronic package and method for manufacturing the same of the present disclosure can simplify the manufacturing process to achieve higher yield and shorter process cycle time.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a photonic component having a first surface and a second surface opposite to the first surface, wherein the first surface is defined with an electrical bonding region and an optical coupling region that are non-overlapping with each other;
an electronic component disposed on the electrical bonding region and electrically connected to the photonic component; and
an optical component disposed on the optical coupling region and optically connected to the photonic component.

2. The electronic package of claim 1, wherein the first surface is an upper surface of the photonic component, and the second surface is a lower surface of the photonic component.

3. The electronic package of claim 1, wherein the electronic component has an active surface and an inactive surface opposite to the active surface, and the active surface of the electronic component is attached onto the electrical bonding region in a flip-chip manner and is electrically connected to the photonic component via a plurality of conductive components.

4. The electronic package of claim 1, wherein the optical coupling region includes an optical coupling surface, a grating or an optical guide element is disposed on the optical coupling surface, and the photonic component is optically connected to the optical component via the grating or the optical guide element.

5. The electronic package of claim 4, wherein the optical coupling region further includes a limiting structure located outside the optical coupling surface, and the limiting structure is configured for limiting a position of the optical component when the optical component is optically connected to the grating or the optical guide element.

6. The electronic package of claim 1, further comprising:
a carrying structure electrically connected to the second surface of the photonic component such that the carrying structure is electrically connected to the electronic component via the photonic component.

7. The electronic package of claim 6, wherein the second surface of the photonic component the carrying structure is disposed on and is electrically connected to the carrying structure via a plurality of conductors.

8. The electronic package of claim 6, further comprising:
a heat dissipation member attached to the electronic component and coupled to the carrying structure.

9. The electronic package of claim 8, further comprising a bonding layer and an adhesive layer, wherein the heat dissipation member includes a sheet body and a support part, the sheet body of the heat dissipation member is attached to the electronic component via the bonding layer, and the support part of the heat dissipation member is coupled to the carrying structure via the adhesive layer.

10. A method for manufacturing an electronic package, comprising:
providing a photonic component, having a first surface and a second surface opposite to the first surface, wherein the first surface is defined with an electrical bonding region and an optical coupling region that are non-overlapping with each other;
disposing an electronic component on the electrical bonding region so as to electrically connect the electronic component to the photonic component; and
disposing an optical component on the optical coupling region so as to optically connect the optical component to the photonic component.

11. The method of claim 10, wherein the first surface is an upper surface of the photonic component, and the second surface is a lower surface of the photonic component.

12. The method of claim 10, further comprising:
disposing the electronic component on the electrical bonding region in a flip-chip manner via an active surface of the electronic component and a plurality of conductive components, to electrically connect the electronic component to the photonic component.

13. The method of claim 10, wherein the optical coupling region includes an optical coupling surface for a grating or an optical guide element to be disposed thereon, and the photonic component is optically connected to the optical component via the grating or the optical guide element.

14. The method of claim 13, wherein the optical coupling region further includes a limiting structure located outside the optical coupling surface, and the limiting structure is configured for limiting a position of the optical component when the optical component is optically connected to the grating or the optical guide element.

15. The method of claim 10, further comprising:
disposing the photonic component, the electronic component and the optical component on a carrying structure, so that the carrying structure is electrically connected to the electronic component via the photonic component.

16. The method of claim 15, wherein the photonic component is disposed on the carrying structure and is electrically connected to the carrying structure by the second surface via a plurality of conductors.

17. The method of claim 15, further comprising:
attaching a heat dissipation member to the electronic component, and coupling the heat dissipation member to the carrying structure.

18. The method of claim 17, wherein the heat dissipation member includes a sheet body and a support part,
Such that the sheet body of the heat dissipation member is attached to the electronic component via a bonding layer
and the support part of the heat dissipation member is coupled to the carrying structure via an adhesive layer.
